(19) United States
(12) Patent Application Publication
(10) Pub. No.: US 2026/0341646 A1
(43) Pub. Date: Oct. 29, 2026

(54) PLASMA PROCESSING APPARATUS AND PLASMA PROCESSING METHOD

(71) Applicant: Tokyo Electron Limited, Tokyo (JP)

(72) Inventor: Takeshi KOBAYASHI, Iwate (JP)

(21) Appl. No.: 19/650,058

(22) Filed: Apr. 16, 2026

(30) Foreign Application Priority Data
Apr. 23, 2025 (JP) 2025-071835

(51) Int. Cl. H01J 37/32; C23C 16/34; C23C 16/455; C23C 16/505; C23C 16/52; H10P 14/60; H10P 14/694

(52) U.S. Cl. CPC H01J 37/32568; C23C 16/345; C23C 16/45536; C23C 16/45544; C23C 16/505; C23C 16/52; H01J 37/3244; H10P 14/6336; H10P 14/6339; H10P 14/69433; H01J 2237/332

(57) ABSTRACT

A plasma processing apparatus includes: a processing container that accommodates a substrate; a plasma box formed in the processing container; an internal electrode inserted into the plasma box; an external electrode disposed on an outer surface of a side wall of the plasma box; an RF power supply that supplies a radio-frequency voltage to the internal electrode; and a first switch that switches between a state where the external electrode is grounded and a state where the external electrode is ungrounded.

### CROSS REFERENCES TO RELATED APPLICATIONS

This application is based on and claims priority from Japanese Patent Application No. 2025-071835, filed on Apr. 23, 2025, with the Japan Patent Office, the disclosure of which is incorporated herein in its entirety by reference.

### TECHNICAL FIELD

The present disclosure relates to a plasma processing apparatus and a plasma processing method.

### BACKGROUND

Japanese Patent Laid-Open Publication No. 2024-007905 discloses a plasma processing apparatus including: a partition wall provided so as to cover an opening in a side wall of a processing container and form an internal space communicating with an interior of the processing container; an internal electrode disposed in the internal space and supplied with RF power; and an external electrode grounded outside the partition wall. Japanese Patent Laid-open Publication No. 2024-131906 discloses a plasma processing apparatus in which a first switch is disposed in a voltage supply line connecting one of a pair of electrodes arranged with a plasma box interposed therebetween to a matching box, and a second switch is disposed in a voltage supply line connecting the other electrode to the matching box.

### SUMMARY

A plasma processing apparatus according to an aspect of the present disclosure includes: a processing container that accommodates a substrate; a plasma box formed in the processing container; an internal electrode inserted into the plasma box; an external electrode disposed on an outer surface of a side wall of the plasma box; a radio-frequency (RF) power supply that supplies a radio-frequency voltage to the internal electrode; and a first switch that switches between a state where the external electrode is grounded and a state where the external electrode is ungrounded.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical cross-sectional view illustrating a plasma processing apparatus, according to an embodiment.

FIG. 2 is a horizontal cross-sectional view illustrating the plasma processing apparatus, according to the embodiment.

FIG. 3 is a cross-sectional view illustrating an example of a plasma generation unit.

FIG. 4 is a schematic view illustrating an example of an internal electrode and an external electrode.

FIG. 5 is a view illustrating an example of a circuit connected to the internal electrode.

FIG. 6 is a view illustrating an example of a circuit connected to the external electrode.

FIG. 7 is a view illustrating another example of a circuit connected to the external electrode.

FIG. 8 is a view (1) illustrating an example of voltage waveforms of the internal electrode and the external electrode.

FIG. 9 is a view (2) illustrating an example of voltage waveforms of the internal electrode and the external electrode.

FIG. 10 is a flowchart illustrating a plasma processing method, according to an embodiment.

FIG. 11 is a time chart illustrating the plasma processing method, according to the embodiment.

FIG. 12 is a view illustrating results of observation of plasma emission.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, non-limiting and exemplary embodiments of the present disclosure will be described with reference to the accompanying drawings. Throughout the accompanying drawings, the same or corresponding members or components are denoted by the same or corresponding reference numerals, and redundant descriptions thereof will be omitted.

### Plasma Processing Apparatus

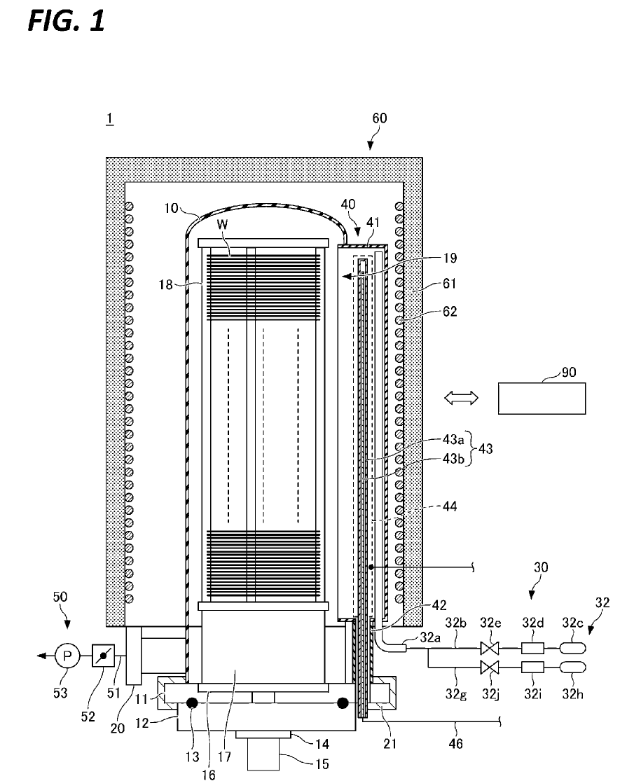

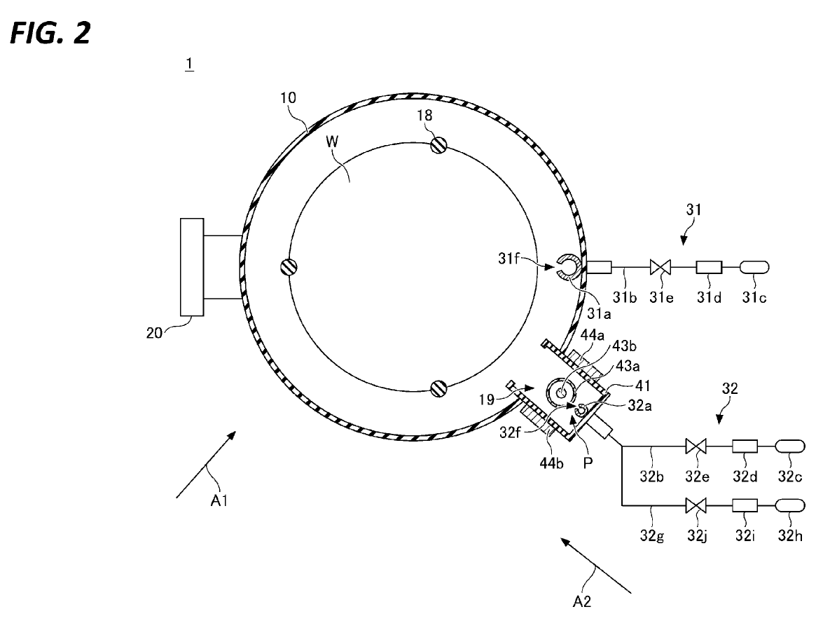

FIG. 1 is a vertical cross-sectional view illustrating a plasma processing apparatus 1, according to an embodiment. FIG. 2 is a horizontal cross-sectional view illustrating the plasma processing apparatus 1, according to the embodiment. As illustrated in FIGS. 1 and 2, the plasma processing apparatus 1 is a batch-type apparatus that simultaneously processes a plurality of substrates W, for example, 50 to 200 substrates W. Each substrate W is, for example, a semiconductor wafer such as a silicon wafer.

The plasma processing apparatus 1 includes a processing container 10, a gas supply unit 30, a plasma generation unit 40, an exhaust unit 50, a heating unit 60, and a control unit 90.

The processing container 10 has a cylindrical shape with a ceiling and an open lower end. The interior of the processing container 10 is capable of being depressurized. The processing container 10 accommodates therein a plurality of substrates W arranged in multiple tiers. The processing container 10 is formed of, for example, quartz.

A bottom flange 11 is provided at the lower end of the processing container 10. The bottom flange 11 is supported by a metal flange 21. The metal flange 21 is provided so as to sandwich an outer edge of the bottom flange 11 via a seal member 22 such as an O-ring. The metal flange 21 is formed of, for example, stainless steel. A lid 12 is airtightly attached to a lower surface of the bottom flange 11 via a seal member 13 such as an O-ring. Accordingly, the opening at the lower end of the processing container 10 is airtightly closed. The lid 12 is formed of, for example, stainless steel. A rotary shaft 15 is provided at a central portion of the lid 12 so as to pass therethrough via a magnetic fluid seal 14. The rotary shaft 15 is rotatable relative to the lid 12. The lid 12 and the rotary shaft 15 are movable upward and downward relative to the processing container 10. A rotary table 16 is provided at an upper end of the rotary shaft 15. A boat 18 is placed on the rotary table 16 via a heat insulating cylinder 17. The heat insulating cylinder 17 and the boat 18 are formed of, for example, quartz. The heat insulating cylinder 17 prevents heat dissipation from the opening at the lower end of the processing container 10. The boat 18 is movable upward and downward integrally with the lid 12. The boat 18 is rotatable integrally with the rotary shaft 15. The boat 18 holds a plurality of substrates W arranged in multiple tiers in a vertical direction.

A rectangular opening 19 extending in the vertical direction is provided in a side wall of the processing container 10. The length of the opening 19 in the vertical direction is, for example, equal to or substantially equal to the length of the boat 18. The opening 19 is covered by a plasma box 41. The plasma box 41 forms an internal space P. The internal space P communicates with the interior of the processing container 10 via the opening 19.

An exhaust port 20 is provided in a lower portion of the side wall of the processing container 10. The interior of the processing container 10 is exhausted by an exhaust unit 50 via the exhaust port 20.

The gas supply unit 30 includes a source gas supply unit 31 and a reaction gas supply unit 32.

The source gas supply unit 31 includes a gas supply pipe 31a inserted into the interior of the processing container 10, and a gas supply path 31b provided outside the processing container 10. In the gas supply path 31b, a source gas source 31c, a mass flow controller 31d, and a valve 31e are provided in this order from an upstream side to a downstream side in a gas flow direction. The supply timing of the source gas from the source gas source 31c is controlled by the valve 31e, and the flow rate thereof is adjusted to a predetermined flow rate by the mass flow controller 31d. The source gas flows from the gas supply path 31b into the gas supply pipe 31a, and is ejected from the gas supply pipe 31a into the interior of the processing container 10.

As for the source gas, for example, dichlorosilane gas is used. However, the source gas is not limited to dichlorosilane gas. In addition to dichlorosilane gas, for example, monochlorosilane gas, trichlorosilane gas, silicon tetrachloride gas, or hexachlorodisilane gas may be used for the source gas. By supplying these gases to a substrate W, a layer containing silicon (Si) (Si-containing layer) may be formed on a substrate W. Since the source gas contains a halogen element, the Si-containing layer contains the halogen element in addition to Si.

The reaction gas supply unit 32 includes a gas supply pipe 32a inserted into the internal space P, and gas supply paths 32b and 32g provided outside the processing container 10.

In the gas supply path 32b, a nitriding gas source 32c, a mass flow controller 32d, and a valve 32e are provided in this order from an upstream side to a downstream side in a gas flow direction. The supply timing of the nitriding gas from the nitriding gas source 32c is controlled by the valve 32e, and the flow rate thereof is adjusted to a predetermined flow rate by the mass flow controller 32d. The nitriding gas flows from the gas supply path 32b into the gas supply pipe 32a, and is ejected from the gas supply pipe 32a into the internal space P.

The nitriding gas is an example of a reaction gas. The nitriding gas is a gas that nitrides the Si-containing layer. As for the nitriding gas, for example, ammonia (NH₃) gas, organic hydrazine compound gas, amine-based gas, NO gas, N₂O gas, or NO₂ gas may be used. As for the organic hydrazine compound gas, for example, hydrazine (N₂H₄) gas, diazene (N₂H₂) gas, or monomethylhydrazine (MMH) gas may be used. As for the amine-based gas, for example, monomethylamine gas may be used.

In the gas supply path 32g, a modifying gas source 32h, a mass flow controller 32i, and a valve 32j are provided in this order from an upstream side to a downstream side in a gas flow direction. The supply timing of the modifying gas from the modifying gas source 32h is controlled by the valve 32j, and the flow rate thereof is adjusted to a predetermined flow rate by the mass flow controller 32i. The modifying gas flows from the gas supply path 32g into the gas supply pipe 32a, and is ejected from the gas supply pipe 32a into the internal space P.

The modifying gas is an example of a reaction gas. The modifying gas is a gas that modifies the Si-containing layer. Modification of the Si-containing layer includes, for example, removing a halogen element contained in the Si-containing layer. By removing the halogen element, dangling bonds of Si may be formed. As a result, the Si-containing layer may be activated, and nitriding of the Si-containing layer may be facilitated. As for the modifying gas, for example, nitrogen gas, hydrogen gas, ammonia gas, or a gas containing any one of these gases may be used.

The gas supply pipe 31a is formed of, for example, quartz. The gas supply pipe 31a extends linearly along a vertical direction in the vicinity of an inner surface of the processing container 10, is bent in an L-shape at a lower portion of the processing container 10, and penetrates a side wall of the processing container 10 to extend to the outside of the processing container 10. A plurality of gas ejection ports 31f are provided in a portion of the gas supply pipe 31a located inside the processing container 10. The plurality of gas ejection ports 31f are provided at predetermined intervals along the vertical direction. Each gas ejection port 31f ejects the source gas in a horizontal direction.

The gas supply pipe 32a is formed of, for example, quartz. The gas supply pipe 32a extends linearly along a vertical direction in the vicinity of an inner surface of the plasma box 41, penetrates a bottom surface of the plasma box 41, and extends to the outside of the processing container 10. A plurality of gas ejection ports 32fare provided in a portion of the gas supply pipe 32a located in the internal space P. The plurality of gas ejection ports 32f are provided at predetermined intervals along the vertical direction. Each gas ejection port 32f ejects the nitriding gas and the modifying gas in a horizontal direction.

The gas supply unit 30 may mix a plurality of types of gases and eject the mixed gas from a single gas supply pipe. For example, the gas supply pipe 31a may be configured to eject an inert gas into the interior of the processing container 10. For example, the gas supply pipe 32a may be configured to eject an inert gas into the internal space P. The gas supply unit 30 may further include, in addition to the gas supply pipe 31a and the gas supply pipe 32a, another gas supply pipe configured to supply another gas.

The plasma generation unit 40 generates plasma from the nitriding gas and the modifying gas ejected from the gas ejection ports 32f of the gas supply pipe 32a. The plasma generation unit 40 will be described later.

The exhaust unit 50 includes an exhaust passage 51, a pressure adjustment valve 52, and a vacuum pump 53. The exhaust passage 51 is connected to the exhaust port 20. The exhaust unit 50 adjusts the pressure inside the processing container 10 by the pressure adjustment valve 52 while exhausting the interior of the processing container 10 by the vacuum pump 53.

The heating unit 60 is provided around the processing container 10. The heating unit 60 includes a heater chamber 61 and a heater wire 62. The heater chamber 61 has a cylindrical shape with a ceiling. The heater wire 62 is provided in a spiral shape on an inner surface of the heater chamber 61. The heating unit 60 heats each substrate W accommodated inside the processing container 10 by heat generated from the heater wire 62.

The control unit 90 is, for example, a computer. The control unit 90 includes a computing unit and a storage unit. The storage unit stores a program for controlling various processes executed in the plasma processing apparatus 1. The computing unit reads and executes the program stored in the storage unit, thereby controlling operation of the plasma processing apparatus 1.

The program (e.g., computer program product) may be provided in a form recorded on a removable storage medium such as a memory card, an optical disc, or a hard disk drive (HDD), and the control unit 90 reads the program from the storage medium and stores the program in the storage unit. The storage unit includes a storage medium such as an HDD, a solid state drive (SSD), or an electronically erasable programmable read only memory (EEPROM). The program may be written in advance to the storage medium of the storage unit. For example, the control unit 90 may obtain a program distributed by a remote server device via a network or other communication.

The control unit 90 is, for example, an electronic circuit such as a central processing unit (CPU), a graphics processing unit (GPU), a field programmable gate array (FPGA), or an application specific integrated circuit (ASIC). The control unit 90 executes various control operations described herein by executing instruction codes stored in a storage medium such as memory, or by being circuit-designed for a specific application.

### Plasma Generation Unit

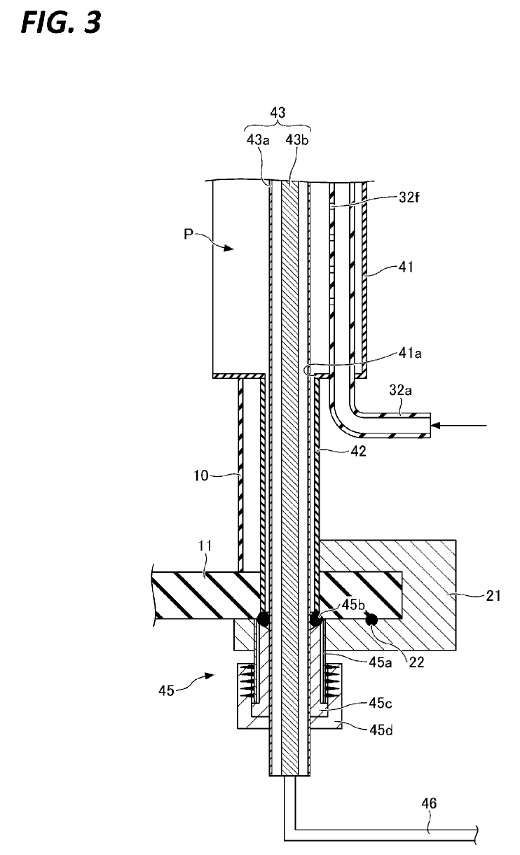

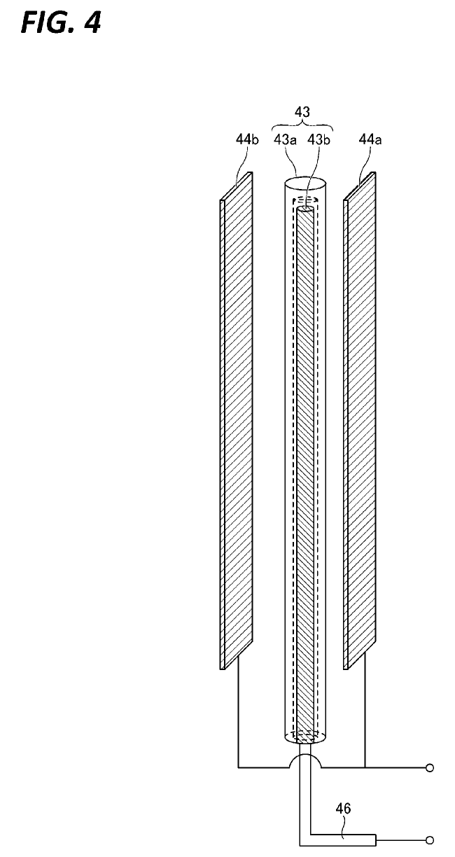

An example of the plasma generation unit 40 included in the plasma processing apparatus 1 will be described with reference to FIGS. 2-7.

The plasma generation unit 40 includes a plasma box 41, an introduction pipe 42, an internal electrode 43, an external electrode 44, a seal portion 45, voltage supply lines 46 and 47, an RF power supply 48, and a matching unit 49.

The plasma box 41 is provided on a portion of a side wall of the processing container 10. The plasma box 41 extends along a vertical direction. The plasma box 41 is airtightly welded to the side wall of the processing container 10. The plasma box 41 has a concave shape in a horizontal cross section. The plasma box 41 covers the opening 19 and forms an internal space P communicating with the interior of the processing container 10. The gas supply pipe 32a is provided in the internal space P. The plasma box 41 is formed of, for example, quartz. An introduction opening 41a into which the internal electrode 43 is inserted is provided in a bottom surface of the plasma box 41.

The introduction pipe 42 is airtightly welded to a bottom surface of the plasma box 41. The introduction pipe 42 is formed of, for example, quartz. The introduction pipe 42 has a cylindrical shape, covers the introduction opening 41a, and has an interior communicating with the internal space P via the introduction opening 41a.

The internal electrode 43 penetrates the plasma box 41, and is removably and airtightly inserted into the internal space P. The internal electrode 43 includes an insulating tube 43aand a rod-shaped electrode 43b.

The insulating tube 43a has an elongated cylindrical shape with a sealed upper end. The insulating tube 43a penetrates the plasma box and is airtightly inserted into the internal space P, and extends along the vertical direction. The atmosphere inside the insulating tube 43a may be, for example, air or an inert gas. The pressure inside the insulating tube 43amay be, for example, atmospheric pressure. The outer diameter of the insulating tube 43a is smaller than the inner diameter of the introduction opening 41a and the inner diameter of the introduction pipe 42. In this case, the insulating tube 43a is insertable into the internal space P with a gap formed between the insulating tube 43a and the plasma box 41, and is insertable into the introduction pipe 42 with a gap formed between the insulating tube 43a and the introduction pipe 42. The insulating tube 43a is formed of, for example, quartz. The insulating tube 43a may be formed of ceramics such as alumina.

The rod-shaped electrode 43b has an elongated cylindrical shape and is inserted into the insulating tube 43a. The lower end of the rod-shaped electrode 43b is drawn out from the lower end of the insulating tube 43a into the atmosphere, and is connected to the RF power supply 48 via the voltage supply line 46, the matching unit 49, and the voltage supply line 47. A radio-frequency voltage is supplied from the RF power supply 48 to the rod-shaped electrode 43b. Since the rod-shaped electrode 43b is installed in the internal space P, it is used at a plasma processing temperature (e.g., 400 °C) or higher. The material of the rod-shaped electrode 43bmay be a metal having low resistivity, and copper or iron may be used. However, since copper and iron have a relatively large diffusion coefficients in quartz, a nickel alloy having a relatively high heat resistance and oxidation resistance may be used from the viewpoint of avoiding metal contamination inside the processing container 10.

The external electrode 44 includes a first external electrode 44a and a second external electrode 44b. Each of the first external electrode 44a and the second external electrode 44b has an elongated rectangular plate shape of which the length direction is the vertical direction. The first external electrode 44a and the second external electrode 44b are fixed to an outer surface of a side wall of the plasma box 41. The first external electrode 44a and the second external electrode 44b are disposed to face each other. In this case, when a radio-frequency voltage is supplied to the internal electrode 43, a capacitively coupled plasma (CCP) is generated between the internal electrode 43 and the first external electrode 44a, and between the internal electrode 43 and the second external electrode 44b. Accordingly, plasma may be generated over a wide range of the internal space P. However, the external electrode 44 may include only one of the first external electrode 44a and the second external electrode 44b. The first external electrode 44a and the second external electrode 44b are configured to be grounded via a switch 71.

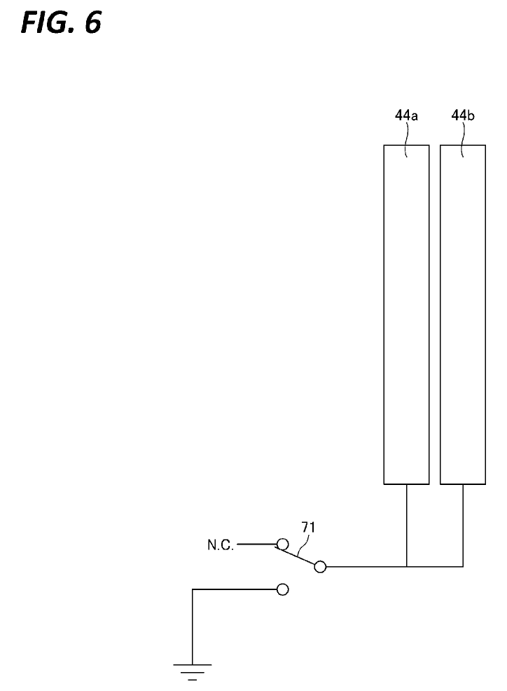

FIG. 6 is a diagram illustrating an example of a circuit connected to the external electrode 44. The circuit illustrated in FIG. 6 includes a switch 71. The switch 71 is configured to be switchable between a state where the first external electrode 44a and the second external electrode 44b are connected to a non-ground-side terminal and a state where the first external electrode 44a and the second external electrode 44b are connected to a ground-side terminal. When the first external electrode 44a and the second external electrode 44b are connected to the non-ground-side terminal, the first external electrode 44a and the second external electrode 44b are ungrounded. When the first external electrode 44a and the second external electrode 44b are connected to the ground-side terminal, the first external electrode 44a and the second external electrode 44b are grounded. The non-ground-side terminal is, for example, a non-connection (N.C.). The switch 71 is an example of the first switch.

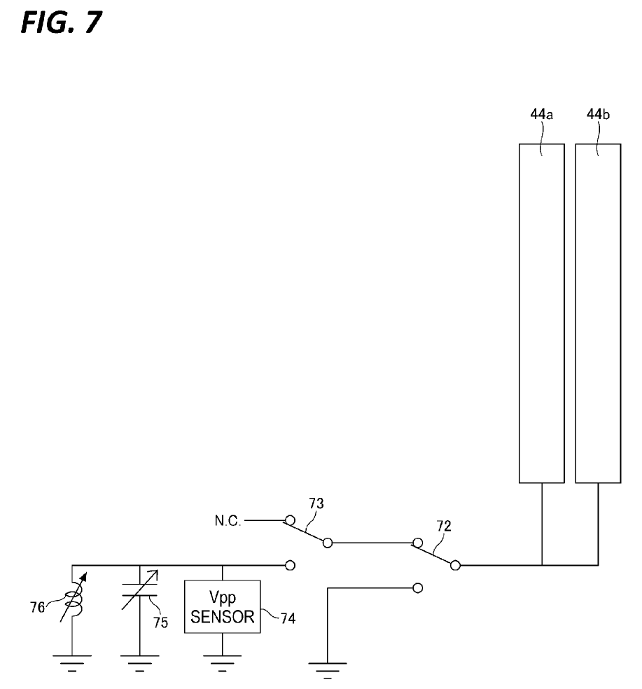

FIG. 7 is a view illustrating another example of a circuit connected to the external electrode 44. The circuit illustrated in FIG. 7 includes a switch 72, a switch 73, a Vpp sensor 74, a variable capacitor 75, and a variable coil 76. The switch 72 is configured to be switchable between a state where the first external electrode 44a and the second external electrode 44b are connected to a non-ground-side terminal via the switch 73 and a state where the first external electrode 44a and the second external electrode 44b are connected to a ground-side terminal. The switch 72 is an example of the first switch. The switch 73 is configured to be switchable between a state where the first external electrode 44a and the second external electrode 44b are connected to the non-ground-side terminal and a state where the first external electrode 44a and the second external electrode 44b are connected to the variable capacitor 75 and the variable coil 76. When the first external electrode 44a and the second external electrode 44b are connected to the non-ground-side terminal, the first external electrode 44a and the second external electrode 44b are ungrounded. The switch 73 is an example of the second switch. The Vpp sensor 74, the variable capacitor 75, and the variable coil 76 are connected in parallel. The control unit 90 controls the phase of the voltage of the first external electrode 44a and the second external electrode 44b by adjusting the capacitance of the variable capacitor 75 and the inductance of the variable coil 76. In the example of FIG. 7, the variable capacitor 75 and the variable coil 76 are provided; however, only one of the variable capacitor 75 and the variable coil 76 may be provided.

The seal portion 45 airtightly seals a gap at the lower end of the introduction pipe 42. The seal portion 45 includes an inner cylindrical member 45a, a seal member 45b, a sleeve 45c, and an outer cylindrical member 45d.

The inner cylindrical member 45a is provided so as to penetrate a bottom wall of the metal flange 21. The inner cylindrical member 45a is formed integrally with, for example, the metal flange 21. The inner cylindrical member 45a has a male thread portion on an outer circumferential surface thereof.

The seal member 45b is provided between the bottom flange 11 and both the insulating tube 43a and the sleeve 45c. The seal member 45b is, for example, an O-ring.

The sleeve 45c is inserted into the inner cylindrical member 45a. The sleeve 45cmoves upward to crush the seal member 45b at the upper end thereof. Accordingly, the seal member 45b is pressed against the insulating tube 43a, the sleeve 45c, and the bottom flange 11 at three points, thereby airtightly sealing a gap at the lower end of the introduction pipe 42.

The outer cylindrical member 45d has, on an inner circumferential surface thereof, a female thread portion that is threadedly engaged with the male thread portion of the inner cylindrical member 45a. By screwing the female thread portion of the outer cylindrical member 45d with the male thread portion of the inner cylindrical member 45a, the sleeve 45c moves upward. The outer cylindrical member 45d is, for example, a nut.

The RF power supply 48 supplies a radio-frequency voltage to the rod-shaped electrode 43b. Accordingly, plasma is generated from the nitriding gas and the modifying gas supplied to the internal space P. The frequency of the radio-frequency voltage is, for example, 13.56 MHz.

The matching unit 49 is connected in series between the rod-shaped electrode 43b and the RF power supply 48 via the voltage supply lines 46 and 47. A switch 461 is disposed between the matching unit 49 and the rod-shaped electrode 43b. The switch 461 is provided, for example, outside the matching unit 49. The switch 461 may be provided inside the matching unit 49. The matching unit 49 includes a first variable capacitor 491, a second variable capacitor 492, a first variable coil 493, a second variable coil 494, a fixed coil 495, a Vpp sensor 496, and an RF sensor 497. The fixed coil 495 and the RF sensor 497 are connected in series to the voltage supply line 46 in this order from the rod-shaped electrode 43b side. The Vpp sensor 496, the first variable capacitor 491, and the second variable capacitor 492 are connected in parallel. The first variable coil 493 is connected in series to the first variable capacitor 491, and one end thereof is grounded. The second variable coil 494 is connected to the second variable capacitor 492, and one end thereof is grounded.

The control unit 90 causes the RF sensor 497 to detect a reflected wave with respect to the radio-frequency voltage applied from the RF power supply 48 to the rod-shaped electrode 43b. The control unit 90 adjusts the capacitances of the first variable capacitor 491 and the second variable capacitor 492, and the inductances of the first variable coil 493 and the second variable coil 494, according to the detected reflected wave. Accordingly, the matching unit 49 performs matching between an output impedance of the RF power supply 48 and a load impedance on the plasma side by adjusting its own impedance. The Vpp sensor 496 detects a voltage supplied to the rod-shaped electrode 43b.

### Switch Setting

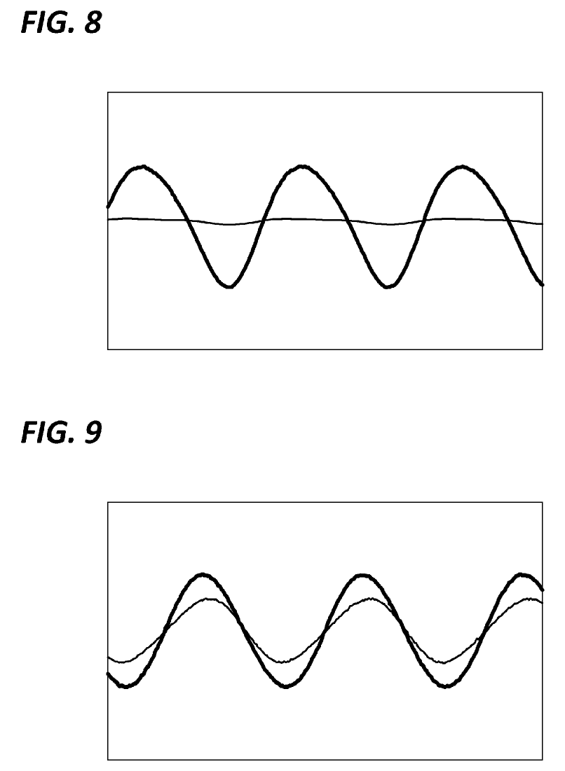

FIGS. 8 and 9 are views illustrating an example of voltage waveforms of the internal electrode 43 and the external electrode 44. In FIGS. 8 and 9, the voltage waveform of the internal electrode 43 is indicated by a thick solid line, and the voltage waveform of the external electrode 44 is indicated by a thin solid line.

The control unit 90 adjusts a potential difference between the internal electrode 43 and the external electrode 44 by controlling settings of the switch 461 and the switch 71.

FIG. 8 illustrates voltage waveforms of the internal electrode 43 and the external electrode 44 when the switch 461 is set to be turned ON and the switch 71 is connected to the ground-side terminal. As illustrated in FIG. 8, when the switch 461 is set to be turned ON, the internal electrode 43 is connected to the RF power supply 48, and therefore a radio-frequency voltage is supplied to the internal electrode 43. When the switch 71 is connected to the ground-side terminal, the external electrode 44 is grounded, and therefore the voltage of the external electrode 44 becomes substantially zero. Accordingly, the potential difference between the internal electrode 43 and the external electrode 44 becomes large.

FIG. 9 illustrates voltage waveforms of the internal electrode 43 and the external electrode 44 when the switch 461 is set to be turned ON and the switch 71 is connected to the non-ground-side terminal. As illustrated in FIG. 9, when the switch 461 is set to be turned ON, the internal electrode 43 is connected to the RF power supply 48, and therefore a radio-frequency voltage is supplied to the internal electrode 43. When the switch 71 is connected to the non-ground-side terminal, a voltage having the same phase as, or substantially the same phase as, a phase of the voltage of the internal electrode 43, and having an effective value lower than an effective value of the voltage of the internal electrode 43, is generated at the external electrode 44. Accordingly, the potential difference between the internal electrode 43 and the external electrode 44 becomes small. As a result, the sheath voltage becomes small, and damage inside the plasma box 41 may be reduced. Consequently, generation of particles caused by damage inside the plasma box 41 may be reduced.

### Plasma Processing Method

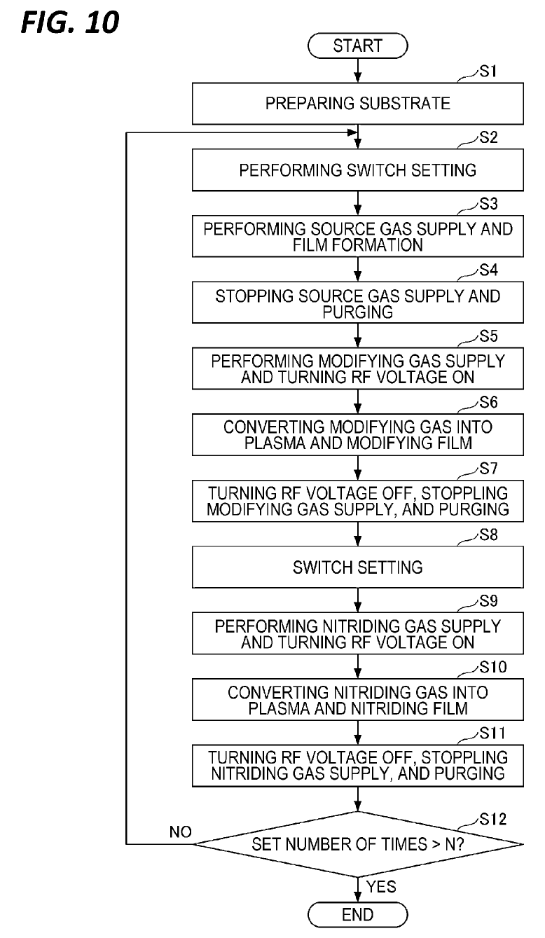

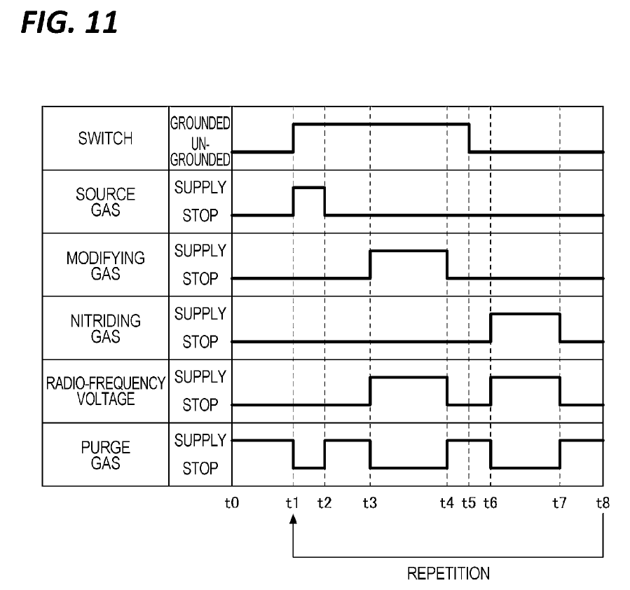

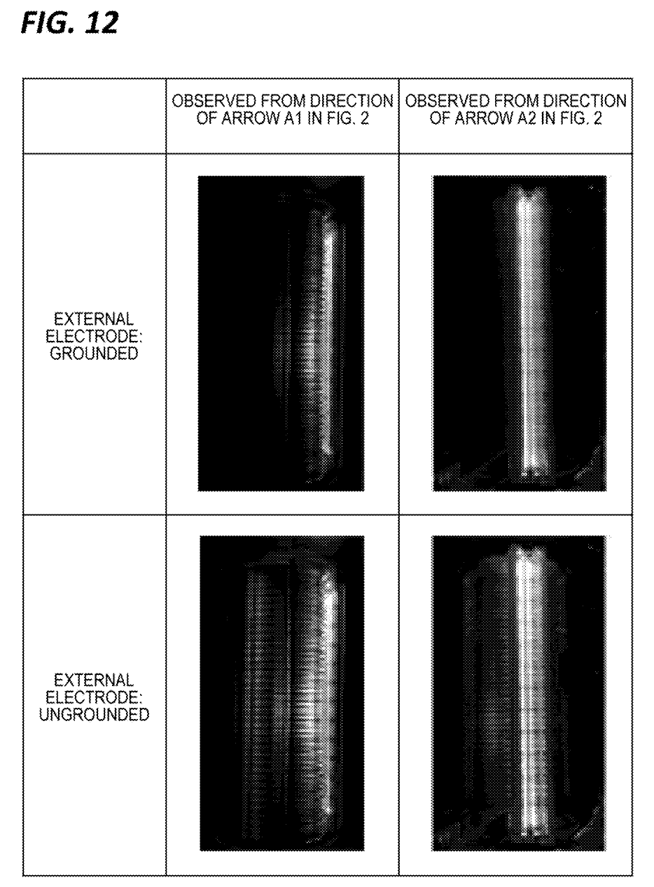

FIG. 10 is a flowchart illustrating a plasma processing method, according to an embodiment. FIG. 11 is a time chart illustrating the plasma processing method, according to the embodiment.

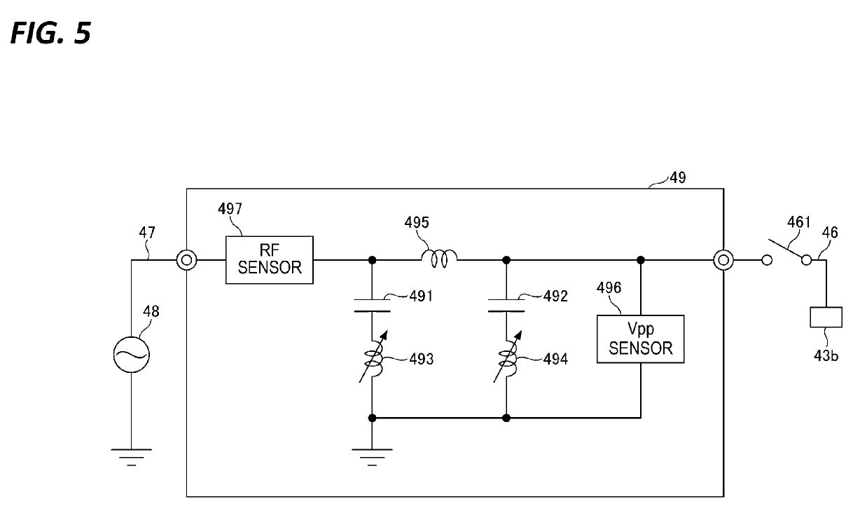

The plasma processing method according to the embodiment is performed under the control of the control unit 90. The plasma processing apparatus 1 executes a process of forming a nitride film on a plurality of substrates W by atomic layer deposition (ALD), in which the plurality of substrates W are accommodated inside the processing container 10 and a plurality of steps are repeated. The film to be formed is not limited to a nitride film. The plasma processing method according to the embodiment is executed using, for example, the circuit configurations of FIGS. 5 and 6. However, the plasma processing method according to the embodiment may be executed using the circuit configurations of FIGS. 5 and 7.

First, in step S1, the control unit 90 carries the boat 18 holding substrates W into the processing container 10 to prepare the process. In step S1, outside the processing container 10, a transfer apparatus places a plurality of substrates W on the boat 18. The boat 18 horizontally holds the plurality of substrates W with intervals therebetween in the vertical direction. Next, a lifting mechanism raises the lid 12 and the boat 18. Together with the boat 18, the substrates W are carried into the processing container 10, and the opening at the lower end of the processing container 10 is sealed by the lid 12.

In the time chart of FIG. 11, time t0 indicates an initial state, and the switch 71 is in a state connected to the non-ground-side terminal. At time t0, supply of source gas, modifying gas, and nitriding gas and plasma generation (application of radio-frequency voltage from the RF power supply 48) are not performed, and only purge gas is supplied. The purge gas may be nitrogen gas, argon gas, another inert gas, or a combination thereof.

Next, in step S2, the control unit 90 performs a switch setting. The control unit 90 controls the switch 71 to be connected to the ground-side terminal such that the first external electrode 44a and the second external electrode 44b are grounded before plasma is generated in step S5. In this case, when a radio-frequency voltage is supplied to the internal electrode 43 in the modifying steps of steps S5 and S6, the potential difference between the internal electrode 43 and the external electrode 44 becomes large. In this case, since plasma is mainly generated inside the plasma box 41, ions in the plasma are less likely to reach edge portions of the substrates W. Accordingly, ion damage at the edge portions of the substrates W may be reduced.

Next, in step S3, the control unit 90 supplies a source gas and causes the source gas to be adsorbed onto the substrates W. In step S3, the control unit 90 forms a Si-containing layer. Supply of the source gas is performed from time t1 to time t2 as illustrated in FIG. 11. Between time t1 and time t2, supply of the purge gas is stopped. In step S3, while the interior of the processing container 10 is exhausted by the exhaust unit 50, the source gas is supplied into the processing container 10 by the source gas supply unit 31. Accordingly, the Si-containing layer is formed on each of the substrates W. The source gas is, for example, dichlorosilane gas. The duration of step S3 is, for example, 1 second or more and 10 seconds or less.

Next, in step S4, the control unit 90 performs a purge step. Step S4 is performed from time t2 to time t3 illustrated in FIG. 11. At time t2 in FIG. 11, the control unit 90 stops supply of the source gas, and supplies a purge gas into the processing container 10 while exhausting the interior of the processing container 10 by the exhaust unit 50. Accordingly, remaining gas inside the processing container 10 is replaced with the purge gas. The duration of step S4 is, for example, 3 seconds or more and 10 seconds or less. The purge gas may be supplied from, for example, the reaction gas supply unit 32.

Next, in steps S5 and S6, the control unit 90 performs a modifying step. Steps S5 and S6 are performed from time t3 to time t4 illustrated in FIG. 11. Between time t3 and time t4, supply of the purge gas is stopped. In step S5, while exhausting the interior of the processing container 10 by the exhaust unit 50, the control unit 90 supplies a modifying gas into the processing container 10 by the reaction gas supply unit 32. The modifying gas is, for example, nitrogen gas. In step S5, the control unit 90 applies a radio-frequency voltage to the internal electrode 43 by the RF power supply 48. Accordingly, plasma is ignited in the internal space P, the modifying gas is converted into plasma, and the Si-containing layer on each of the substrates W is modified. Modification of the Si-containing layer includes, for example, removing a halogen element contained in the Si-containing layer. By removing the halogen element, dangling bonds of Si may be formed. As a result, the Si-containing layer may be activated, and nitriding of the Si-containing layer may be promoted. In steps S5 and S6, the control unit 90 controls the switch 461 to be turned on such that a radio-frequency voltage is supplied from the RF power supply 48 to the internal electrode 43. In steps S5 and S6, the control unit 90 controls the switch 71 to be connected to the ground-side terminal so as to maintain a state where the external electrode 44 is grounded. The frequency of the radio-frequency voltage supplied by the RF power supply 48 is, for example, 13.56 MHz or 14.56 MHz. The durations of steps S5 and S6 are, for example, 3 seconds or more and 60 seconds or less.

Next, in step S7, the control unit 90 performs a purge step. Step S7 is performed from time t4 to time t6 illustrated in FIG. 11. At time t4 in FIG. 11, the control unit 90 stops supply of the modifying gas and stops application of the radio-frequency voltage. Further, while exhausting the interior of the processing container 10 by the exhaust unit 50, the control unit 90 supplies a purge gas into the processing container 10 to replace the gas remaining inside the processing container 10 with the purge gas. The duration of step S7 is, for example, 3 seconds or more and 10 seconds or less. The purge gas may be supplied from, for example, the reaction gas supply unit 32.

Next, in step S8, the control unit 90 performs setting of the switch 71 at time t5 illustrated in FIG. 11. The control unit 90 controls the switch 71 to be connected to the non-ground-side terminal such that the first external electrode 44a and the second external electrode 44b are ungrounded before plasma is generated in step S9. In this case, when a radio-frequency voltage is supplied to the internal electrode 43 in the nitriding steps of steps S9 and S10, the potential difference between the internal electrode 43 and the external electrode 44 becomes small. Accordingly, the sheath voltage becomes small, and damage inside the plasma box 41 may be reduced. As a result, generation of particles caused by damage inside the plasma box 41 may be reduced.

Next, in steps S9 and S10, the control unit 90 performs a nitriding step. Steps S9 and S10 are performed from time t6 to time t7 illustrated in FIG. 11. Between time t6 and time t7, supply of the purge gas is stopped. In step S9, while exhausting the interior of the processing container 10 by the exhaust unit 50, the control unit 90 supplies a nitriding gas into the processing container 10 by the reaction gas supply unit 32. The nitriding gas is, for example, ammonia gas. In step S9, a radio-frequency voltage is applied from the RF power supply 48 to the internal electrode 43. Accordingly, plasma is ignited in the internal space P, the nitriding gas is converted into plasma, and the Si-containing layer on each of the substrates W is nitrided. The durations of steps S9 and S10 are, for example, 5 seconds or more and 120 seconds or less.

Next, in step S11, the control unit 90 performs a purge step. Step S11 is performed from time t7 to time t8 illustrated in FIG. 11. At time t7 in FIG. 11, the control unit 90 stops supply of the nitriding gas and stops application of the radio-frequency voltage. Further, while exhausting the interior of the processing container 10 by the exhaust unit 50, the control unit 90 supplies a purge gas into the processing container 10 to replace the remaining gas inside the processing container 10 with the purge gas. The duration of step S11 is, for example, 3 seconds or more and 10 seconds or less. The purge gas may be, for example, nitrogen gas, and may be supplied from, for example, the reaction gas supply unit 32.

Next, in step S12, the control unit 90 determines whether the process has been repeated more than a set number of times N (N ≥ 1). The set number of times N is preset. When the control unit 90 determines that the process has not been repeated more than the set number of times N, the control unit 90 returns the process to step S2 and repeats the cycle of steps S2 to S11. In step S12, when the control unit 90 determines that the process has been repeated more than the set number of times N, the control unit 90 terminates the process.

### Effects

In the plasma processing apparatus 1 according to the embodiment, the plasma processing apparatus 1 includes an RF power supply 48 that supplies a radio-frequency voltage to the internal electrode 43, and switches 71 and 72 that switch between a state where the external electrode 44 is grounded and a state where the external electrode 44 is ungrounded. In this case, when the switch 71 is connected to the non-ground-side terminal, the potential difference between the internal electrode 43 and the external electrode 44 may be reduced. Accordingly, the sheath voltage becomes small, and damage inside the plasma box 41 may be reduced. As a result, generation of particles caused by damage inside the plasma box 41 may be reduced.

When the plasma processing apparatus 1 further includes a switch 73 that switches between a state where the external electrode 44 is connected to at least one of the variable capacitor 75 and the variable coil 76 and a state where the external electrode 44 is ungrounded, the phase of the voltage of the external electrode 44 may be controlled.

When the phase of the voltage of the internal electrode 43 and the phase of the voltage of the external electrode 44 are the same, a potential difference between the internal electrode 43 and the external electrode 44 may be easily reduced.

When the effective value of the voltage of the internal electrode 43 is higher than the effective value of the voltage of the external electrode 44, damage inside the plasma box 41 may be easily reduced.

When the external electrode 44 includes a first external electrode 44a and a second external electrode 44b arranged to face each other, damage inside the plasma box 41 may be readily reduced.

When the control unit 90 controls the switches 71 and 72 such that the external electrode is in a grounded state in the modifying step, plasma is mainly generated inside the plasma box 41, and therefore ions in the plasma are less likely to reach edge portions of the substrates W. Accordingly, ion damage at the edge portions of the substrates W may be reduced.

When the control unit 90 controls the switches 71 and 72 such that the external electrode 44 is in an ungrounded state in the nitriding step, spreading of plasma from the interior of the plasma box 41 to the interior of the processing container 10 may be increased. Accordingly, film characteristics such as in-plane film thickness and film quality across each of the substrates W may be improved.

### First Experiment

In a first experiment, an influence of a grounded state and an ungrounded state of the external electrode 44 included in the plasma processing apparatus 1 was evaluated on the degree of damage to an inner surface of a side wall of the plasma box 41.

In the first experiment, in a state where the external electrode 44 was grounded and in a state where the external electrode 44 was ungrounded, the control unit 90 controlled the plasma processing apparatus 1 to generate plasma from ammonia gas inside the plasma box 41 and to maintain the plasma for a predetermined period of time. Specifically, the control unit 90 controlled the exhaust unit 50 to exhaust the interior of the processing container 10, controlled the reaction gas supply unit 32 to supply ammonia gas into the processing container 10, and controlled the RF power supply 48 to apply a radio-frequency voltage to the internal electrode 43. Further, the control unit 90 controlled the switch 71 to place the external electrode 44 in the grounded state and in the ungrounded state.

Next, by observing the interior of the plasma box 41, presence or absence of damage inside the plasma box 41 was confirmed.

As a result of the experiment, in the grounded state of the external electrode 44, damage was observed inside the plasma box 41. In contrast, in the ungrounded state of the external electrode 44, no damage was observed inside the plasma box 41. From this result, it was found that, when plasma is generated from ammonia gas inside the plasma box 41, damage inside the plasma box 41 may be reduced by placing the external electrode 44 in the ungrounded state.

### Second Experiment

In a second experiment, an influence of a grounded state and an ungrounded state of the external electrode 44 included in the plasma processing apparatus 1 was evaluated on spreading of plasma from the interior of the plasma box 41 to the interior of the processing container 10.

In the second experiment, in a state where the external electrode 44 was grounded and in a state where the external electrode 44 was ungrounded, the control unit 90 controlled the plasma processing apparatus 1 to generate plasma from nitrogen gas inside the plasma box 41 and to maintain the plasma for a predetermined period of time. Specifically, the control unit 90 controlled the exhaust unit 50 to exhaust the interior of the processing container 10, controlled the reaction gas supply unit 32 to supply nitrogen gas into the processing container 10, and controlled the RF power supply 48 to apply a radio-frequency voltage to the internal electrode 43. Further, the control unit 90 controlled the switch 71 to place the external electrode 44 in the grounded state and in the ungrounded state.

Next, while plasma was maintained inside the plasma box 41, plasma emission inside the plasma box 41 and inside the processing container 10 was observed.

FIG. 12 is a view illustrating results of observation of plasma emission. The upper row of FIG. 12 illustrates plasma emission in the grounded state of the external electrode 44. The lower row of FIG. 12 illustrates plasma emission in the ungrounded state of the external electrode 44. The left column of FIG. 12 illustrates plasma emission when the processing container 10 and the plasma box 41 were observed from a direction of arrow A1 in FIG. 2. The right column of FIG. 12 illustrates plasma emission when the processing container 10 and the plasma box 41 were observed from a direction of arrow A2 in FIG. 2.

As illustrated in the upper row of FIG. 12, in the grounded state of the external electrode 44, plasma emission was observed in an entirety of the interior of the plasma box 41 and in a portion of the interior of the processing container 10. In contrast, as illustrated in the lower row of FIG. 12, in the ungrounded state of the external electrode 44, plasma emission was observed in the entirety of the interior of the plasma box 41 and in the entirety of the interior of the processing container 10. That is, in the ungrounded state of the external electrode 44, spreading of plasma from the interior of the plasma box 41 to the interior of the processing container 10 was greater than in the grounded state of the external electrode 44. From this result, it was found that spreading of plasma from the interior of the plasma box 41 to the interior of the processing container 10 may be controlled by switching between the grounded state of the external electrode 44 and the ungrounded state of the external electrode 44. By controlling spreading of plasma from the interior of the plasma box 41 to the interior of the processing container 10, film characteristics such as in-plane film thickness and film quality of the substrates W may be controlled.

In the second experiment, similar experiments were also conducted in cases where ammonia gas and hydrogen gas were used instead of nitrogen gas as a gas for plasma generation. Also in these cases, a tendency similar to that in the case where nitrogen gas was used as the gas for plasma generation was observed. That is, in the ungrounded state of the external electrode 44, spreading of plasma from the interior of the plasma box 41 to the interior of the processing container 10 was greater than in the grounded state of the external electrode 44.

According to the present disclosure, damage to the interior of the plasma box may be reduced.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be restricting, with the true scope and spirit being indicated by the following claims.

What is claimed is:

1. A plasma processing apparatus comprising:
a processing container configured to accommodate a substrate;
a plasma box formed in the processing container;
an internal electrode inserted into the plasma box;
an external electrode disposed on an outer surface of a side wall of the plasma box;
a radio-frequency (RF) power supply configured to supply a radio-frequency voltage to the internal electrode; and
a first switch configured to switch between a state where the external electrode is grounded and a state where the external electrode is ungrounded.

2. The plasma processing apparatus of claim 1, further comprising:
a second switch configured to switch between a state where the external electrode is connected to at least one of a variable capacitor and a variable coil and a state where the external electrode is ungrounded.

3. The plasma processing apparatus of claim 1, wherein a phase of a voltage of the internal electrode is equal to a phase of a voltage of the external electrode.

4. The plasma processing apparatus of claim 1, wherein an effective value of a voltage of the internal electrode is equal to an effective value of a voltage of the external electrode.

5. The plasma processing apparatus of claim 1, wherein the external electrode includes a first external electrode and a second external electrode that are disposed to face each other.

6. The plasma processing apparatus of claim 1, further comprising:
a reaction gas supply configured to supply a modifying gas into the processing container; and
a controller,
wherein the controller is configured to simultaneously perform controlling the first switch such that the external electrode is in a grounded state, controlling the reaction gas supply such that the modifying gas is supplied into the processing container, and controlling the RF power supply such that the radio-frequency voltage is supplied to the internal electrode.

7. The plasma processing apparatus of claim 1, further comprising:
a reaction gas supply configured to supply a nitriding gas into the processing container; and
a controller,
wherein the controller is configured to simultaneously perform controlling the first switch such that the external electrode is in an ungrounded state, controlling the reaction gas supply such that the nitriding gas is supplied into the processing container, and controlling the RF power supply such that the radio-frequency voltage is supplied to the internal electrode.

8. A plasma processing method comprising:
providing a plasma processing apparatus including a processing container configured to accommodate a substrate, a plasma box formed in the processing container, an internal electrode inserted into the plasma box, an external electrode disposed on an outer surface of a side wall of the plasma box, a radio-frequency (RF) power supply configured to supply a radio-frequency voltage to the internal electrode, a first switch configured to switch between a state where the external electrode is grounded and a state where the external electrode is ungrounded, and a reaction gas supply configured to supply a modifying gas into the processing container; and
simultaneously performing controlling the first switch such that the external electrode is in the grounded state, controlling the reaction gas supply such that the modifying gas is supplied into the processing container, and controlling the RF power supply such that the radio-frequency voltage is supplied to the internal electrode.

9. A plasma processing method comprising:
providing a plasma processing apparatus including a processing container configured to accommodate a substrate, a plasma box formed in the processing container, an internal electrode inserted into the plasma box, an external electrode disposed on an outer surface of a side wall of the plasma box, a radio-frequency (RF) power supply configured to supply a radio-frequency voltage to the internal electrode, a first switch configured to switch between a state where the external electrode is grounded and a state where the external electrode is ungrounded, and a reaction gas supply configured to supply a nitriding gas into the processing container; and
simultaneously performing controlling the first switch such that the external electrode is in the ungrounded state, controlling the reaction gas supply such that the nitriding gas is supplied into the processing container, and controlling the RF power supply such that the radio-frequency voltage is supplied to the internal electrode.
